(19) United States
(12) Patent Application Publication
(10) Pub. No.: US 2021/0387358 A1
(43) Pub. Date: Dec. 16, 2021

(54) ROBOT HAND AND ROBOT HAVING THE SAME

(71) Applicant: KAWASAKI JUKOGYO KABUSHIKI KAISHA, Kobe-shi, Hyogo (JP)

(72) Inventors: Takayuki FUKUSHIMA, Kobe-shi (JP); Shogo MATSUOKA, Kakogawa-shi (JP)

(73) Assignee: KAWASAKI JUKOGYO KABUSHIKI KAISHA, Kobe-shi, Hyogo (JP)

(21) Appl. No.: 17/287,600

(22) PCT Filed: Nov. 5, 2019
(86) PCT No.: PCT/JP2019/043205

§ 371 Date: Apr. 22, 2021

(30) Foreign Application Priority Data
Nov. 6, 2018 (JP) 2018-208982

(51) Int. Cl. B25J 15/02; H01L 21/687

(52) U.S. Cl. CPC B25J 15/0253; H01L 21/68707

(57) ABSTRACT

A robot hand configured to grip a substrate by contacting an edge of the substrate at least two locations is provided, which includes a base body defining a gripping position at which the center of the substrate is located on a center line extending in a longitudinal direction, a sliding surface provided on a base-end side of a second contacting part on the center line and configured to move with the second contacting part, and a mobile body slid surface provided on the base-end side of the sliding surface on the center line, and moving toward a tip end on the center line to push the sliding surface and move the sliding surface and the second contacting part toward the tip end. When the substrate is gripped, the second contacting part receives a force from the substrate and the surface slides to move the second part toward the base body.

### TECHNICAL FIELD

The present disclosure relates to a robot hand and a robot having the same.

### BACKGROUND ART

Conventionally, a robot hand which grips a substrate by contacting an edge of the substrate at at least two locations is known. Patent Document 1 discloses a wafer transferring robot as one example of such a robot hand.

Patent Document 1 discloses to advance a mover of an ultrasonic motor toward a tip end of a hand, and push a wafer by a mobile claw toward a fixed claw which is fixed to the robot hand on its tip-end side, so as to grip a circumferential edge of the wafer by the mobile claw and the fixed claw.

### REFERENCE DOCUMENT OF CONVENTIONAL ART

### Patent Document

[Patent Document 1] JP2002-264065A

### DESCRIPTION OF THE DISCLOSURE

### Problem to be Solved by the Disclosure

Meanwhile, the robot hand disclosed in Patent Document 1 and other conventional robot hands are generally provided with a base body. The base body defines a center line extending from a base-end side to a tip-end side at the center in a width direction, and a gripping position at which the center of the substrate is located on the center line.

Then, when the conventional robot hand grips the substrate, a part of the robot hand, which pushes the substrate (e.g., the mobile claw in Patent Document 1), receives a reaction force from the substrate and moves to separate from the base body. Accordingly, the conventional robot hand may not be able to certainly grip the substrate.

Therefore, one purpose of the present disclosure is to provide a robot hand and a robot having the robot hand, capable of certainly gripping a substrate.

### Summary of the Disclosure

In order to solve the problem, according to one aspect of the present disclosure, a robot hand configured to grip a substrate by contacting an edge of the substrate at at least two locations is provided. The robot hand includes a base body defining a longitudinal direction connecting a base end to a tip end thereof, a width direction orthogonal to the longitudinal direction, a thickness direction orthogonal to the longitudinal direction and the width direction, a center line extending in the longitudinal direction at the center in the width direction, and a gripping position at which the center of the substrate is located on the center line extending in the longitudinal direction, a first contacting part provided to the base body at the tip-end side and configured to contact a first part of the edge of the substrate when the substrate is gripped, a second contacting part provided on the base-end side of the base body and configured to contact a second part of the edge of the substrate on the center line extending in the longitudinal direction when the substrate is gripped, a sliding surface provided on the base-end side of the second contacting part on the center line extending in the longitudinal direction, and configured to move integrally with the second contacting part, and a mobile body having a slid surface provided on the base-end side of the sliding surface on the center line extending in the longitudinal direction, and configured to, upon the substrate being gripped, move toward the tip end on the center line extending in the longitudinal direction to push the sliding surface by the slid surface and move the sliding surface and the second contacting part toward the tip end. The sliding surface inclines at an acute angle with respect to the base body when seen in the width direction, and the slid surface inclines at an obtuse angle with respect to the base body corresponding to the sliding surface when seen in the width direction. When the substrate is gripped, the second contacting part receives a reaction force from the substrate and the sliding surface slides on the slid surface to move the second contacting part toward the base body.

According to this configuration, when the substrate is gripped, the second contacting part receives the reaction force from the substrate, and the sliding surface slides on the slid surface, and accordingly the second contacting part moves toward the base body. Thus, the second contacting part can be prevented from being moved to separate from the base body by receiving the reaction force from the substrate when the substrate is gripped. As a result, the robot hand according to the present disclosure can certainly grip the substrate.

Both of the second contacting part and the sliding surface may be included in the same member.

According to this configuration, the robot hand according to the present disclosure can have a simple structure.

The robot hand may include a rotary member having a circular edge, and a shaft hole bored at the center thereof when seen in the thickness direction. The second contacting part may be a part of the circular edge of the rotary member. The sliding surface may be a part of an inner wall of the shaft hole of the rotary member. The mobile body may have a shaft part to be inserted into the shaft hole of the rotary member to rotatably support the rotary member in a plane where the longitudinal direction intersects with the width direction. The shaft part may have a tapered part having a cross-sectional area that decreases toward the base body. The slid surface may be a part of an outer surface of the tapered part of the shaft part.

According to this configuration, the edge of the substrate can be prevented from being worn down due to the contact with the second contacting part.

The shaft part may further have a flange on a side separating from the base body more than the tapered part. The robot hand may further include a biasing member provided on the base-body side of the rotary member while the shaft part is inserted into a shaft hole of the biasing member, and configured to bias the rotary member toward the flange.

According to this configuration, since the rotary member is biased toward the flange of the shaft part by the biasing member, the rotary member can be prevented from being moved along the shaft part when the second contacting part of the rotary member is in a steady state where it does not receive the reaction force from the substrate.

The robot hand may further include a motion regulating structure configured to regulate a movable range of the second contacting part and the sliding surface with respect to the slid surface.

According to this configuration, the second contacting part and the sliding surface can be moved with respect to the slid surface within a desired range.

For example, in the thickness direction, an application point of the reaction force from the substrate to the second contacting part may differ from an application point of a thrust that moves the mobile body toward the tip end on the center line extending in the longitudinal direction.

The base body may have a base part provided on the base-end side thereof, and at least two base-branch parts branching from the base part and extending toward the tip end. The second contacting part may be provided near or in contact with a principal surface of the base part, and the first contacting part may be provided protrudingly from a principal surface of each of the at least two base-branch parts.

According to this configuration, since the at least two first contacting parts contact the tip-end side of the substrate, the substrate can be gripped more certainly.

The substrate may be a semiconductor wafer in a disc-shape. The first contacting part may have an arc-shape corresponding to the edge of the semiconductor wafer when seen in the thickness direction.

According to this configuration, the edge of the substrate can be prevented from being worn down due to the contact with the first contacting part. Moreover, since a contacting area of the first contacting part with the substrate increases, the substrate can be gripped further certainly.

The first contacting part may be a part of an engaging member configured to engage with the first part of the edge of the substrate when the substrate is gripped.

According to this configuration, since the first contacting part can engage with the first part of the edge of the substrate, the substrate can be gripped further certainly.

In order to solve the problem, according to another aspect of the present disclosure, a robot is provided, which includes any one of the robot hands described above and a robotic arm to which the robot hand is attached at a tip end of the robotic arm. The robot changes at least a posture of the robotic arm to transfer the substrate while the robot hand grips the substrate.

According to this configuration, since the robot according to the present disclosure includes the robot hand described above, it can certainly grip the substrate.

### Effect of the Disclosure

According to the present disclosure, a robot hand and a robot having the robot hand, capable of certainly gripping a substrate can be provided.

### BRIEF DESCRIPTION OF DRAWINGS

FIG. 1 is a schematic view illustrating the entire configuration of a robot system according to one embodiment of the present disclosure.

FIG. 2 is a schematic view of a robot hand according to this embodiment of the present disclosure when seen in a thickness direction.

FIG. 3 is a cross-sectional view illustrating an engaging member of the robot hand according to this embodiment of the present disclosure, taken along a line III-III in FIG. 2.

FIG. 4 is a cross-sectional view illustrating a guiding member of the robot hand according to this embodiment of the present disclosure, taken along a line IV-IV in FIG. 2.

FIGS. 5(A) and 5(B) are schematic views illustrating a situation where the robot hand according to this embodiment of the present disclosure grips a semiconductor wafer placed vertically, where FIG. 5(A) illustrates a state before the semiconductor wafer is gripped, and FIG. 5(B) illustrates a state where the semiconductor wafer is gripped and lifted.

FIGS. 6(A) and 6(B) are enlarged cross-sectional views illustrating a situation before a second contacting part receives a reaction force from the semiconductor wafer upon the robot hand according to this embodiment of the present disclosure gripping the semiconductor wafer, where FIG. 6(A) illustrates a mobile body, a rotary member, and their peripheral part, and FIG. 6(B) illustrates a shaft member, the rotary member, and their peripheral part.

FIGS. 7(A) and 7(B) are enlarged cross-sectional views illustrating a state where the second contacting part receives the reaction force from the semiconductor wafer when the robot hand according to this embodiment of the present disclosure grips the semiconductor wafer, where FIG. 7(A) illustrates the mobile body, the rotary member, and their peripheral part, and FIG. 7(B) illustrates the shaft member, the rotary member, and their peripheral part.

FIGS. 8(A) and 8(B) are schematic views of a situation, when seen from above, where the robot system according to this embodiment of the present disclosure takes the semiconductor wafer accommodated in an accommodating device to the outside, where FIG. 8(A) illustrates an initial state, and FIG. 8(B) illustrates a state where the robot hand is rotated to extend vertically.

FIGS. 9(A) and 9(B) are schematic views of a situation, when seen from above, where the robot system according to this embodiment of the present disclosure takes the semiconductor wafer accommodated in the accommodating device to the outside, where FIG. 9(A) illustrates a state where the semiconductor wafer is gripped by the robot hand, and FIG. 9(B) illustrates a state where the semiconductor wafer is taken out.

FIG. 10 is an enlarged cross-sectional view illustrating a shaft member and its peripheral part of a robot hand according to Modification 1 of this embodiment of the present disclosure.

FIGS. 11(A) and 11(B) are enlarged views of a sliding surface, a slid surface, and their peripheral part in a state before a second contacting part receives a reaction force from a semiconductor wafer upon a robot hand according to Modification 2 of this embodiment of the present disclosure gripping the semiconductor wafer, where FIG. 11(A) is an external perspective view, and FIG. 11(B) is a cross-sectional view.

FIGS. 12(A) and 12(B) are enlarged views of the sliding surface, the slid surface, and their peripheral part in a state where the second contacting part receives the reaction force from the semiconductor wafer when the robot hand according to Modification 2 of this embodiment of the present disclosure grips the semiconductor wafer, where FIG. 12(A) is an external perspective view, and FIG. 12(B) is a cross-sectional view.

FIG. 13 is a schematic view illustrating behavior of a mobile body, a rotary member, and their peripheral part in a state where a second contacting part receives a reaction force from a semiconductor wafer when a conventional robot hand grips the semiconductor wafer.

### MODE FOR CARRYING OUT THE DISCLOSURE

Hereinafter, a robot hand, a robot and a robot system having the robot hand according to one embodiment of the present disclosure, are described with reference to the accompanying drawings. Note that this embodiment does not limit the present disclosure. Moreover, below, the same reference characters are given to the same or corresponding elements throughout the drawings to omit redundant description.

### Robot System 10

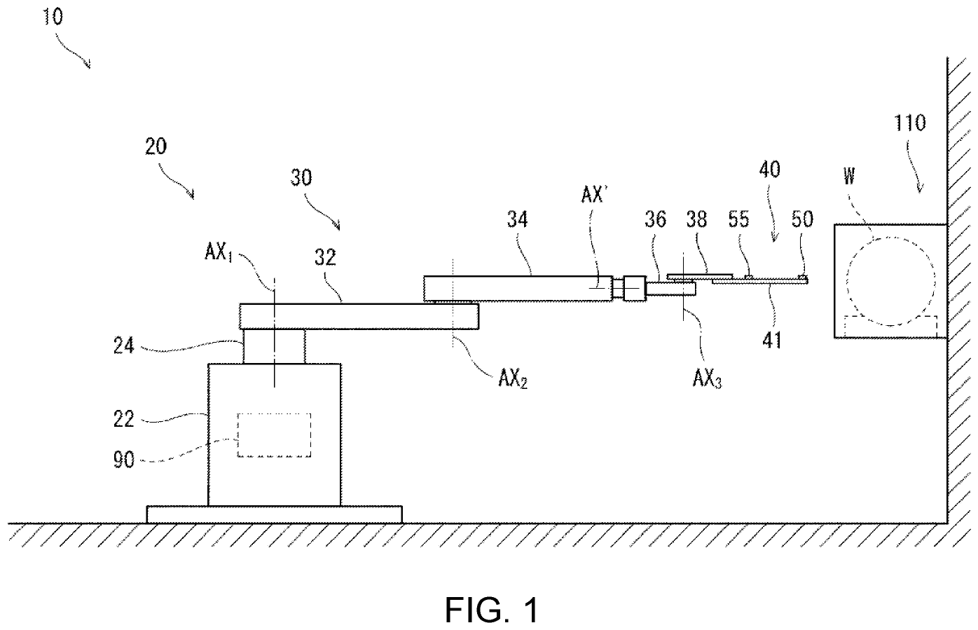

FIG. 1 is a schematic view illustrating the entire configuration of the robot system according to this embodiment. As illustrated in FIG. 1, a robot system 10 according to this embodiment is provided with a robot 20 which transfers a semiconductor wafer W (a substrate) in a disc-shape by gripping it, and an accommodating device 110 which accommodates the semiconductor wafer W.

### Robot 20

As illustrated in FIG. 1, the robot 20 according to this embodiment is a horizontally articulated 3-axis robot having a turnable wrist part 36, and is provided with three joint axes. The robot 20 includes a pedestal 22, and a lifting shaft 24 provided to an upper surface of the pedestal 22 and vertically expandable and contractible. The lifting shaft 24 is comprised of, for example, an air cylinder (not illustrated) so as to be expandable and contractible.

Moreover, the robot 20 is further provided with a robotic arm 30 attached to an upper-end part of the lifting shaft 24, a robot hand 40 attached to a tip-end part of the robotic arm 30, and a robot controlling device 90 which controls operation of the robotic arm 30 and the robot hand 40.

### Robotic Arm 30

The robotic arm 30 has a first link 32 extending horizontally, a second link 34 coupled to a tip-end part of the first link 32 and extending horizontally, the wrist part 36 coupled to a tip-end part of the second link 34, and a hand-base part 38 coupled to a tip-end part of the wrist part 36.

The first link 32 is coupled at its base-end part to the upper-end part of the lifting shaft 24 via a joint axis which is driven by a servomotor (not illustrated). Therefore, the first link 32 is rotatable about a first axial line AX₁ vertically extending and passing through an axial center of the lifting shaft 24.

The second link 34 is coupled at its base-end part to the tip-end part of the first link 32 via a joint axis which is driven by a servomotor (not illustrated). Therefore, the second link 34 is rotatable about a second axial line AX₂ vertically extending and passing through the tip-end part of the first link 32.

The wrist part 36 is coupled at its base-end part to the tip-end part of the second link 34 via a turning axis which is driven by a servomotor (not illustrated). Therefore, the wrist part 36 is turnable about a turning axial line AX′ horizontally extending and passing through an axial center of the second link 34.

The hand-base part 38 is coupled at its base-end part to the tip-end part of the wrist part 36 via a joint axis AX₃ which is driven by a servomotor (not illustrated). Therefore, the hand-base part 38 is rotatable about a third axial line AX₃ vertically extending and passing through the tip-end part of the wrist part 36.

### Robot Hand 40

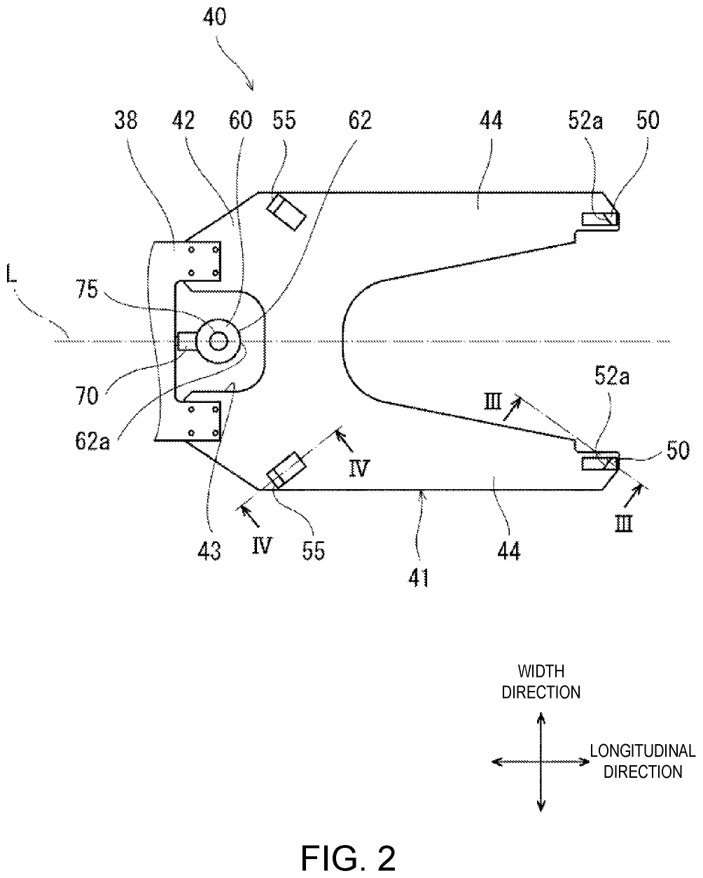

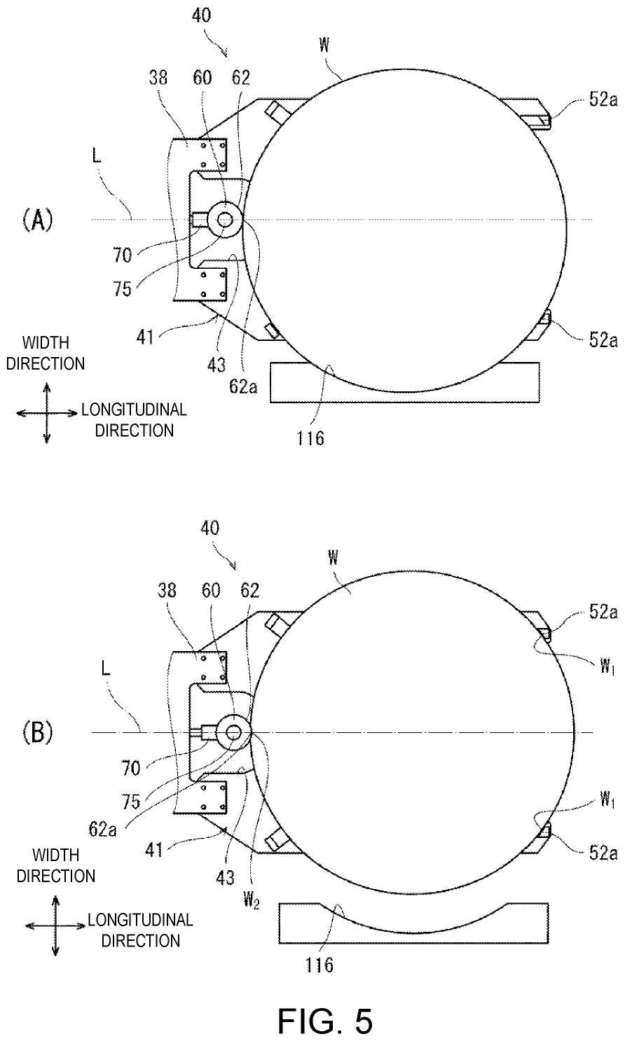

FIG. 2 is a schematic view of the robot hand according to this embodiment, when seen in a thickness direction. As illustrated in FIG. 2, the robot hand 40 according to this embodiment is attached to a tip-end part of the hand-base part 38. The robot hand 40 has a base body 41 defining a longitudinal direction connecting its base end to its tip end, a width direction orthogonal to the longitudinal direction, and the thickness direction orthogonal to the longitudinal direction and the width direction. The base body 41 further defines a center line L extending in the longitudinal direction at the center in the width direction, and a gripping position at which the center of the semiconductor wafer W is located on the center line L (see FIG. 5(B)).

The base body 41 has a base part 42 provided to a base-end side thereof, and two base-branch parts 44 branched from the base part 42 so as to extend toward the tip end. The base part 42 and the two base-branch parts 44 are integrally formed. Moreover, a rectangular notch 43 when seen in the thickness direction is formed on a base-end side of the base part 42. By the base body 41 being structured as described above, it has a substantially Y-shape when seen in the thickness direction.

The robot hand 40 further includes engaging members 50 provided protrudingly from tip-end parts of principal surfaces of the two base-branch parts 44 so as to engage with first parts W₁ (see FIG. 5(B)) on an edge of the semiconductor wafer W, respectively, and guiding members 55 provided protrudingly from both edge parts in the width direction of a principal surface of the base part 42, respectively.

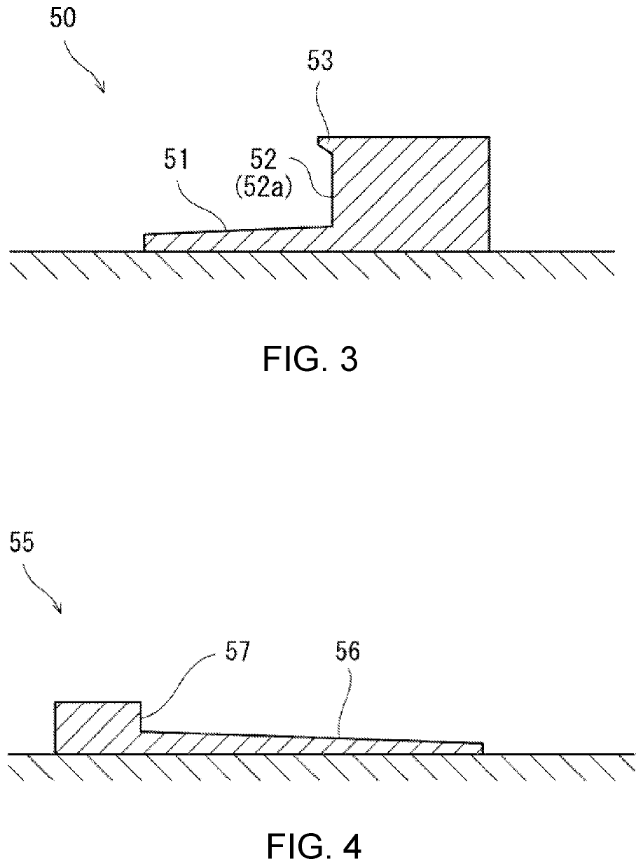

FIG. 3 is a cross-sectional view illustrating the engaging member of the robot hand according to this embodiment, taken along a line III-III in FIG. 2. Each of the two engaging members 50 is fixedly provided to the principal surface of the corresponding base-branch part 44. Note that, as illustrated in FIG. 2, the shapes of the two engaging members 50 are line-symmetry with respect to the center line L. Therefore, here, only one engaging member 50 is described, and similar description of the other engaging member 50 is not repeated.

As illustrated in FIG. 3, the engaging member 50 has an inclining surface 51 inclining to separate from the principal surface of the base-branch part 44 toward the tip end of the principal surface of the base-branch part 44, a standing surface 52 bent from a tip end of the inclining surface 51 so as to stand in the thickness direction of the base body 41, and a flange 53 provided protrudingly from an upper end of the standing surface 52 toward the base end of the base body 41.

In this embodiment, when the semiconductor wafer W is gripped, the standing surface 52 constitutes a first contacting part 52a which contacts the first part W₁ of the edge of the semiconductor wafer W (see FIG. 5(B)). The first contacting part 52a (and the standing surface 52) has an arc-shape when seen in the thickness direction of the base body 41, corresponding to the edge of the semiconductor wafer W.

FIG. 4 is a cross-sectional view illustrating the guiding member of the robot hand according to this embodiment, taken along a line IV-IV in FIG. 2. The two guiding members 55 are fixedly provided to the principal surface of the base part 42. Note that, as illustrated in FIG. 2, the shapes of the two guiding members 55 are line-symmetry with respect to the center line L. Therefore, here, only one guiding member 55 is described, and similar description of the other guiding member 55 is not repeated.

As illustrated in FIG. 4, the guiding member 55 has an inclining surface 56 inclining to approach the principal surface of the base part 42 toward the tip end of the principal surface of the base part 42, a standing surface 57 bent from a tip end of the inclining surface 56 so as to stand in the thickness direction of the base body 41.

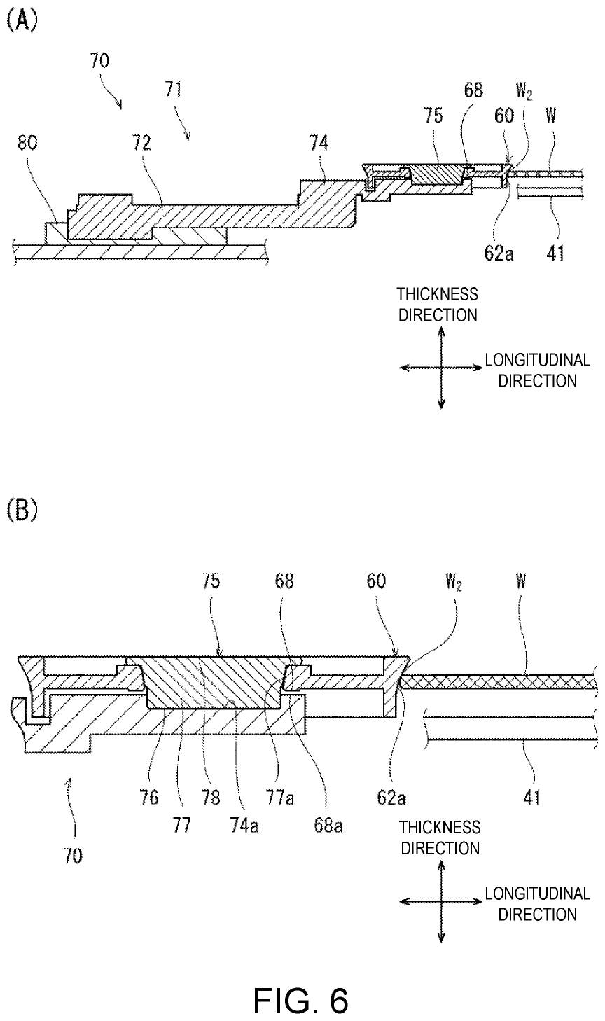

FIGS. 5(A) and 5(B) are schematic views illustrating a situation where the robot hand according to this embodiment grips the vertically placed semiconductor wafer, where FIG. 5(A) illustrates a state before the semiconductor wafer is gripped, and FIG. 5(B) illustrates a state where the semiconductor wafer is gripped and lifted. FIGS. 6(A) and 6(B) are enlarged cross-sectional views illustrating a situation before a second contacting part receives a reaction force from the semiconductor wafer upon the robot hand according to this embodiment gripping the semiconductor wafer, where FIG. 6(A) illustrates a mobile body, a rotary member, and their peripheral part, and FIG. 6(B) illustrates a shaft member, the rotary member, and their peripheral part. Note that FIGS. 6(A) and 6(B) are cross-sectional views when the robot hand 40 is cut in the thickness direction at the position of the center line L illustrated in FIG. 2 and FIGS. 5(A) and 5(B).

As illustrated in FIGS. 5(A), 5(B), 6(A), and 6(B), the robot hand 40 is further provided with a rotary member 60 provided near the principal surface of the base part 42, and a mobile body 70 reciprocatable along the center line L. The rotary member 60 and the mobile body 70 are each provided on the center line L.

The rotary member 60 has a circular edge 62, and a shaft hole 68 is bored at the center of the rotary member 60 when seen in the thickness direction of the base body 41 (i.e., when seen as illustrated in FIGS. 5(A) and 5(B)). The circular edge 62 extends in the thickness direction of the base body 41 from an end part on the base body 41 side, and then, it further extends in the thickness direction of the base body 41 while curving toward the tip end of the base body 41 when seen in the width direction of the base body 41.

In the robot hand 40 according to this embodiment, since the circular edge 62 of the rotary member 60 has the shape as described above, a second part W₂ of the gripped semiconductor wafer W is restricted to move in a direction separating from the base body 41 in the thickness direction. Moreover, since each of the two engaging members 50 has the flange 53, the two engaging members 50 engage with the first parts W₁ of the gripped semiconductor wafer W, respectively. According to this structure, the robot hand 40 can stably grip the semiconductor wafer W.

In this embodiment, when the semiconductor wafer W is gripped, a part of the circular edge 62 of the rotary member 60 constitutes a second contacting part 62a which contacts the second part W₂ of the edge of the semiconductor wafer W (see FIG. 5(B)) on the center line L.

Moreover, an inner wall of the shaft hole 68 of the rotary member 60 inclines at an acute angle with respect to the base body 41 when seen in the width direction of the base body 41. In this embodiment, a part of the inner wall of the shaft hole 68 constitutes a sliding surface 68a which will be described later. Accordingly, in this embodiment, the second contacting part 62a and the sliding surface 68a are both included in the rotary member 60 (in the same member). Moreover, the sliding surface 68a is provided on the base-end side of the second contacting part 62a on the center line L, and is integrally movable with the second contacting part 62a.

As illustrated in FIGS. 6(A) and 6(B), the mobile body 70 has a mobile member 71, and a shaft member 75 (a shaft part) fixed to a tip-end part of the mobile member 71. Here, as illustrated in FIGS. 6(A) and 6(B), the robot hand 40 is further provided with a rail member 80 provided on the opposite side from the rotary member 60 and the shaft member 75 with respect to the base body 41 in the thickness direction of the base body 41, and an actuator (not illustrated) which drives the mobile member 71.

The rail member 80 extends along the center line L, and a base-end part of the mobile member 71 is slidably attached thereto. The actuator may be configured to have, for example, an electric motor and a power transmission mechanism (e.g., a rack and pinion, or a ball screw), or comprised of a pneumatic cylinder, a hydraulic cylinder, etc. Operation of the actuator is controlled by the robot controlling device 90. The actuator may be supported by the hand-base part 38 to which the robot hand 40 is attached.

The mobile member 71 has a first part 72 attached at its base-end part to the rail member 80 and extending along the center line L, and a second part 74 extending along the center line L from an upper surface of a tip-end part of the first part 72. Then, a base-end part of the shaft member 75 is coupled to a concave part 74a formed in an upper surface of a tip-end part of the second part 74. The concave part 74a and the shaft member 75 are each provided to overlap with the notch 43 formed in the base part 42 when seen in the thickness direction of the base body 41 (i.e., when seen as illustrated in FIGS. 5(A) and 5(B)).

The second part 74 of the mobile member 71 is provided so that its upper surface is positioned on the opposite side from the rail member 80 with respect to the base body 41 in the thickness direction of the base body 41. According to the above structure, the mobile member 71 (and the shaft member 75 and the rotary member 60) is reciprocatable along the center line L without obstruction by the base body 41 and the other members. Moreover, according to the above structure, an application point of the reaction force R from the semiconductor wafer W to the second contacting part 62a differs from an application point of a thrust T which moves the mobile body 70 toward the tip end on the center line L, in the thickness direction of the base body 41.

The shaft member 75 has a base-end part 76 coupled to the concave part 74a of the mobile member 71, a tapered part 77 provided to an upper end of the base-end part 76, and a flange 78 radially protruding from an upper end of the tapered part 77. The base-end part 76 and the tapered part 77 of the shaft member 75 have diameters corresponding to the shaft hole 68 of the rotary member 60. A diameter of the flange 78 of the shaft member 75 is larger than that of the shaft hole 68 of the rotary member 60.

In this embodiment, by the base-end part 76 and the tapered part 77 of the shaft member 75 being inserted into the shaft hole 68 of the rotary member 60, a movable range of the rotary member 60 with respect to the shaft member 75 in a plane where the longitudinal direction and the width direction intersect with each other, is regulated. In other words, a movable range of the second contacting part 62a and the sliding surface 68a with respect to a slid surface 77a in the plane where the longitudinal direction and the width direction intersect with each other, is regulated.

Moreover, since an edge part of the shaft hole 68 of the rotary member 60 is sandwiched between an edge part of the concave part 74a of the mobile member 71 and the flange 78 of the shaft member 75, a movable range of the rotary member 60 with respect to the shaft member 75 in the thickness direction is limited. In other words, a movable range of the second contacting part 62a and the sliding surface 68a with respect to the slid surface 77a in the plane where a longitudinal direction and the thickness direction intersect with each other, is regulated.

In this embodiment, by the rotary member 60 being positioned as described above, the mobile member 71 and the shaft member 75 cooperatively constitute a motion regulating structure which regulates the movable range of the rotary member 60 with respect to the shaft member 75. In other words, by the rotary member 60 being positioned as described above, the mobile member 71 and the shaft member 75 cooperatively constitute the motion regulating structure which regulates the movable range of the second contacting part 62a and the sliding surface 68a with respect to the slid surface 77a.

A cross-sectional area of the base-end part 76 of the shaft member 75 is uniform in the thickness direction of the base body 41. On the other hand, the tapered part 77 has a smaller cross-sectional area toward the base body 41 (and the base-end part 76). Therefore, when seen in the width direction of the base body 41, an outer surface of the tapered part 77 inclines at an obtuse angle with respect to the base body 41, corresponding to the inner wall of the shaft hole 68 of the rotary member 60. In this embodiment, a part of the outer surface of the tapered part 77 constitutes the slid surface 77a which will be described later.

According to the structure described above, when the semiconductor wafer W is gripped, the mobile body 70 moves toward the tip end of the base body 41 on the center line L to push the sliding surface 68a of the rotary member 60 by the slid surface 77a of the shaft member 75 and move the rotary member 60 having the sliding surface 68a and the second contacting part 62a toward the tip end of the base body 41.

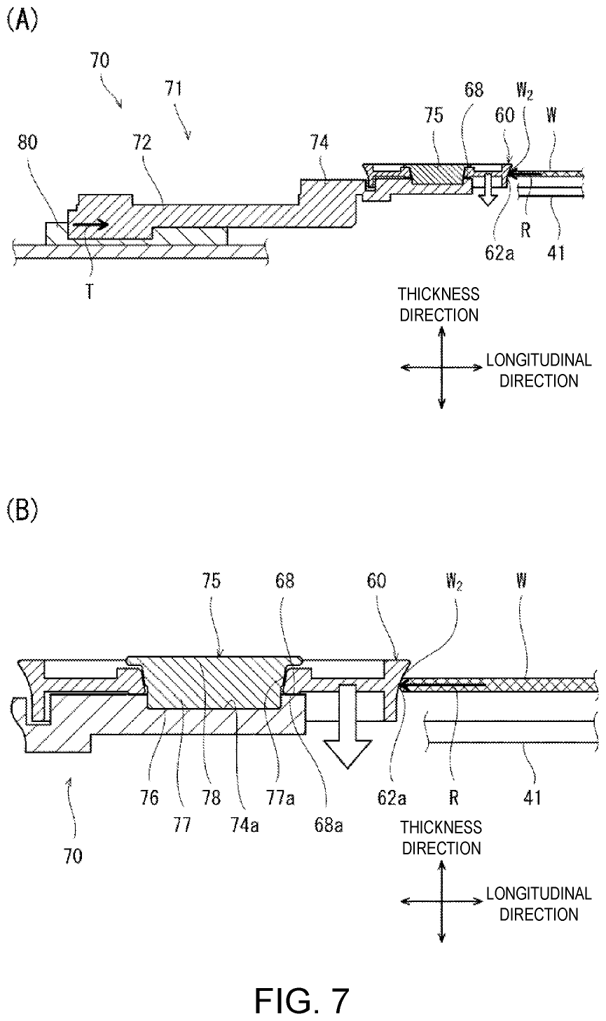

FIGS. 7(A) and 7(B) are enlarged cross-sectional views illustrating a state where the second contacting part receives the reaction force from the semiconductor wafer when the robot hand according to this embodiment grips the semiconductor wafer, where FIG. 7(A) illustrates the mobile body, the rotary member, and their peripheral part, and FIG. 7(B) illustrates the shaft member, the rotary member, and their peripheral part. Note that, similar to FIGS. 6(A) and 6(B), FIGS. 7(A) and 7(B) are cross-sectional views when the robot hand 40 is cut in the thickness direction at the position of the center line L illustrated in FIG. 2 and FIGS. 5(A) and 5(B).

As illustrated in FIGS. 7(A) and 7(B), when the semiconductor wafer W is gripped, the mobile body 70 moves toward the tip end of the base body 41 on the center line L, and the second contacting part 62a of the rotary member 60 receives the reaction force R from the semiconductor wafer W, and thus, the sliding surface 68a of the rotary member 60 slides on the slid surface 77a. Accordingly, as indicated by white arrows in the drawings, the second contacting part 62a of the rotary member 60 moves toward the base body 41.

### Robot Controlling Device 90

The robot controlling device 90 is provided inside the pedestal 22. Although a concrete configuration of the robot controlling device 90 is not particularly limited, it may be implemented by, for example, a known processor (e.g., a CPU) operating in accordance with a program stored in a storage part (e.g., a memory).

### Accommodating Device 110

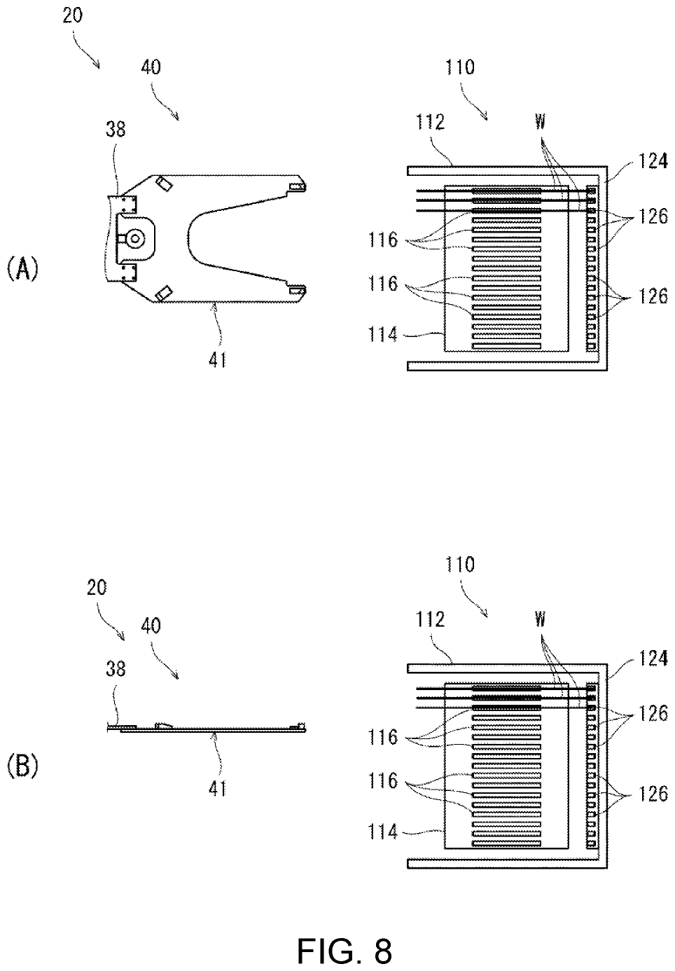

As illustrated in FIG. 1, the accommodating device 110 is provided fixedly on a wall surface at a worksite. Moreover, the accommodating device 110 has a structure to vertically accommodate the semiconductor wafers W so that the semiconductor wafers W extend in the vertical direction. Here, a structure of the accommodating device 110 is described with reference to FIG. 8(A).

FIG. 8(A) is a schematic view illustrating a situation, when seen from above, where the robot system according to this embodiment takes the semiconductor wafer accommodated in the accommodating device to the outside, where FIG. 8(A) illustrates an initial state, and FIG. 8(B) illustrates a state where the robot hand is rotated to extend vertically.

As illustrated in FIG. 8(A), the accommodating device 110 is provided with a shell 112 in a box shape, of which a front surface facing to the robot 20 is opened, and an openable door (not illustrated) provided in front of the shell 112.

A plurality of bottom-plate grooves 116 are formed in an inner surface of a bottom plate 114 of the shell 112. The plurality of bottom-plate grooves 116 each extends in a direction connecting the front surface to a back surface of the shell, and are provided to align in a direction connecting a left surface to a right surface of the shell 112 having an equal interval therebetween (e.g., at 5 mm or above and 15 mm or below). An inner wall of each of the plurality of bottom-plate grooves 116 has, as illustrated in FIGS. 5(A) and 5(B), an arc-shape corresponding to the edge of the semiconductor wafer W, when seen in the direction connecting the left surface to the right surface of the shell 112.

A plurality of back-plate grooves 126 are formed in an inner surface of a back plate 124 of the shell 112. The plurality of back-plate grooves 126 each extends in a direction connecting the bottom surface to an upper surface of the shell 112, and are provided to align in a direction connecting the left surface to the right surface of the shell 112 having an equal interval therebetween (e.g., at 5 mm or above and 15 mm or below). The plurality of back-plate grooves 126 are formed at the same positions as the plurality of bottom-plate grooves 116, in the direction connecting the left surface to the right surface of the shell 112.

According to the structure described above, the accommodating device 110 can fit the edge of the semiconductor wafer W into the bottom-plate groove 116 and the back-plate groove 126 of the shell 112, and thus, a plurality of semiconductor wafers W can be accommodated while being placed vertically.

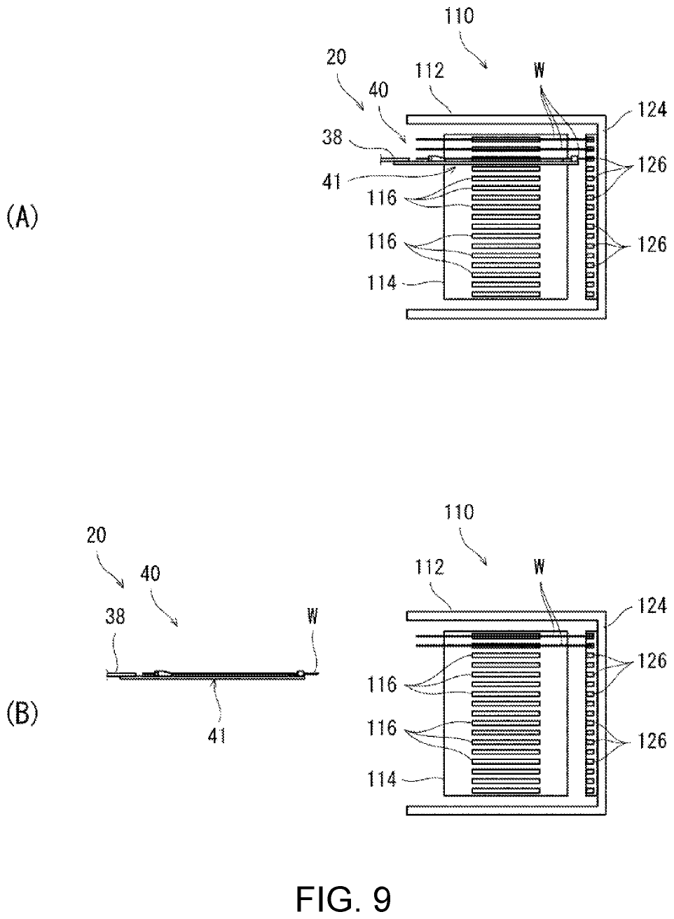

Here, referring to FIGS. 8(A), 8(B), 9(A), and 9(B), one example of a process of taking the semiconductor wafer W vertically accommodated in the accommodating device 110, out of the accommodating device 110, is described. As described above, FIG. 8(A) illustrates the situation where the semiconductor wafer accommodated in the accommodating device is taken out, from the initial state to a state before the wrist part being turned. FIGS. 9(A) and 9(B) are schematic views illustrating a situation, when seen from above, where the robot system according to this embodiment takes the semiconductor wafer accommodated in the accommodating device to the outside, where FIG. 9(A) illustrates a state where the semiconductor wafer is gripped by the robot hand, and FIG. 9(B) illustrates a state where the semiconductor wafer is taken out.

First, the wrist part 36 of the robotic arm 30 is turned from the initial state illustrated in FIG. 8(A) so as to bring the base body 41 of the robot hand 40 to extend vertically as illustrated in FIG. 8(B).

Next, as illustrated in FIG. 9(A), a posture of the robotic arm 30 is changed so that the robot hand 40 is at a position and in a posture grippable of the semiconductor wafer W vertically accommodated in the accommodating device 110. Here, the position and the posture of the robot hand 40 grippable of the semiconductor wafer W vertically accommodated in the accommodating device 110, are a position and a posture where, as illustrated in FIG. 5(A), the standing surfaces 52 of the two engaging members 50, the standing surfaces 57 of the two guiding members 55, and the circular edge 62 of the rotary member 60, are all facing to (or contact) the edge of the semiconductor wafer W.

Then, by the mobile body 70 moving toward the tip end on the center line L, the second contacting part 62a of the rotary member 60 pushes the semiconductor wafer W toward the tip end. Thus, the semiconductor wafer W is pushed by the rotary member 60 from the base-end side of the base body 41 against the standing surfaces 52 of the two engaging members 50. In this manner, the robot hand 40 grips the vertically placed semiconductor wafer W.

Moreover, the robot hand 40 moves, while gripping the semiconductor wafer W, in a direction separating from a position at which the semiconductor wafer W is placed (from the bottom-plate groove 116 in FIG. 5(B)), so that the semiconductor wafer W separates from the bottom-plate groove 116 of the accommodating device 110. This state is illustrated in FIG. 5(B).

Finally, as illustrated in FIG. 9(B), the posture of the robotic arm 30 is changed so as to move the robot hand 40 outside the accommodating device 110. Accordingly, the robot system 10 according to this embodiment can take the semiconductor wafer W vertically accommodated in the accommodating device 110, out of the accommodating device 110.

### Effects

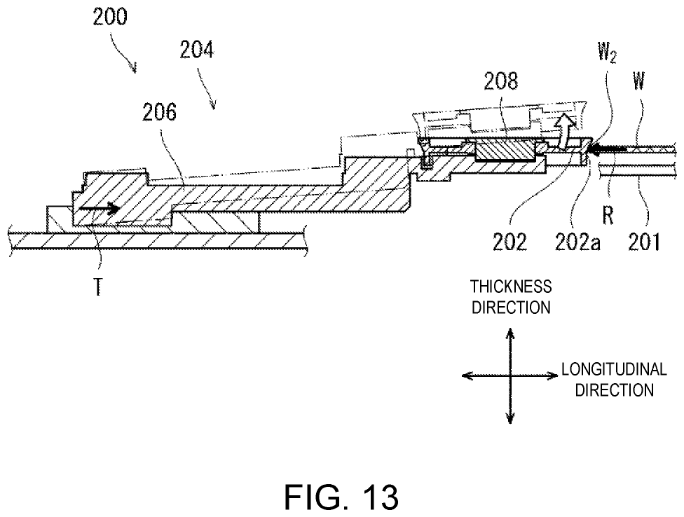

FIG. 13 is a schematic view illustrating behavior of a mobile body, a rotary member, and their peripheral part in a state where a second contacting part receives the reaction force from a semiconductor wafer when a conventional robot hand grips the semiconductor wafer. As illustrated in FIG. 13, when a conventional robot hand 200 grips the semiconductor wafer W, a rotary member 202 pushing the semiconductor wafer W receives the reaction force R from the semiconductor wafer W, and thus, as indicated by a white arrow in the drawing, a mobile body 204 (i.e., a mobile member 206 and a shaft member 208) tends to rotate so as to separate from a base body 201 centering on a base-end part of the mobile body 204. Accompanying to this, a second contacting part 202a of the rotary member 202 moves to separate from the base body 201. As a result, the conventional robot hand 200 may not be able to certainly grip the semiconductor wafer W.

On the other hand, in the robot hand 40 according to this embodiment, when the second contacting part 62a of the rotary member 60 receives the reaction force R from the semiconductor wafer W (the substrate), the sliding surface 68a of the rotary member 60 slides on the slid surface 77a of the mobile body 70. Accordingly, since the second contacting part 62a of the rotary member 60 moves toward the base body 41, the second contacting part 62a can be prevented from being moved to separate from the base body 41 when receiving the reaction force R from the semiconductor wafer W. As a result, the robot hand 40 according to the present disclosure can certainly grip the semiconductor wafer W.

In this embodiment, since the second contacting part 62a and the sliding surface 68a are both included in the rotary member 60 (in the same member), the robot hand 40 according to this embodiment can have a simple structure.

In this embodiment, since the second contacting part 62a is configured as a part of the circular edge 62 of the rotary member 60, and the sliding surface 68a is configured as a part of the outer surface of the tapered part 77 of the shaft member 75, the edge of the semiconductor wafer W can be prevented from being worn down due to the contact with the second contacting part 62a.

In this embodiment, since the mobile member 71 and the shaft member 75 cooperatively constitute the motion regulating structure which regulates the movable range of the second contacting part 62a and the sliding surface 68a with respect to the slid surface 77a, the second contacting part 62a and the sliding surface 68a can be moved with respect to the slid surface 77a within a desired range.

In this embodiment, similar to the conventional robot hand, for example, the application point of the reference force R differs from the application point of the thrust T. Therefore, a moment which rotates the mobile body 70 centering on its base-end part so as to separate from the base body 41, is generated. However, in the robot hand 40 according to this embodiment, the sliding surface 68a of the rotary member 60 slides on the slid surface 77a of the mobile body 70 when the second contacting part 62a of the rotary member 60 receives the reaction force R from the semiconductor wafer W, and thus, the moment can be canceled out.

In this embodiment, the engaging members 50 are provided protrudingly from the principal surfaces of the two base-branch parts 44, respectively. Accordingly, since the two first contacting parts 52a contact the tip-end side of the semiconductor wafer W, the semiconductor wafer W can be gripped more certainly.

In this embodiment, since the first contacting part 52a of the engaging member 50 has an arc-shape corresponding to the edge of the semiconductor wafer W when seen in the thickness direction of the base body 41, the edge of the semiconductor wafer W can be prevented from being worn down due to the contact with the first contacting part 52a. Moreover, since a contacting area of the first contacting part 52a with the semiconductor wafer W increases, the semiconductor wafer W can be gripped further certainly.

In this embodiment, when the semiconductor wafer W is gripped, the first contacting part 52a is configured as a part of the engaging member 50 which engages with the first part W₁ of the edge of the semiconductor wafer W, and it can engage with the first part W₁ of the edge of the semiconductor wafer W. Therefore, the semiconductor wafer W can be gripped further certainly.

Since effects achieved by the robot 20 and the robot system 10 according to this embodiment are the same as those achieved by the robot hand 40, similar description is not repeated here.

### Modification 1

It is apparent for a person skilled in the art from the above description that many improvements and other embodiments of the present disclosure are possible. Therefore, the above description is to be interpreted only as illustration, and it is provided in order to teach a person skilled in the art the best mode for implementing the present disclosure. The details of the structures and/or the functions may be substantially changed, without departing from the spirit of the present disclosure.

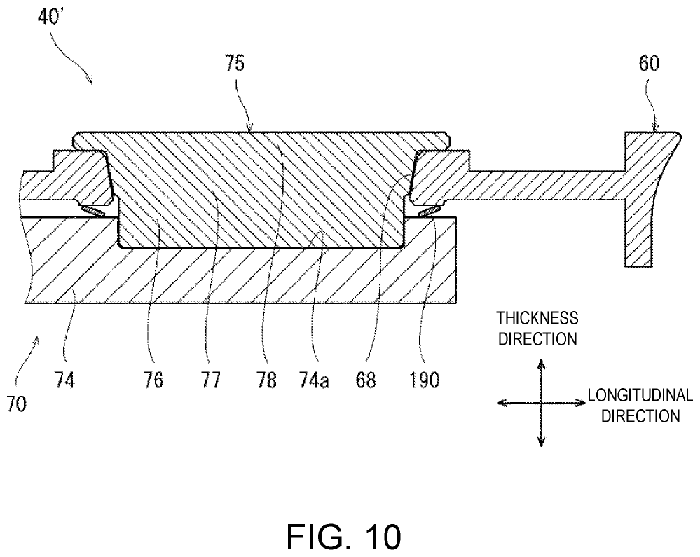

FIG. 10 is an enlarged cross-sectional view illustrating a shaft member and its peripheral part of a robot hand according to Modification 1 of the embodiment described above. Note that the robot hand according to this modification has the same structure as the robot hand 40 according to the embodiment, except for that the robot hand according to this modification is provided with a disc spring 190 (a biasing member). Therefore, the same reference characters are given to the same parts, and similar description is not repeated.

As illustrated in FIG. 10, a robot hand 40′ according to this modification is provided with the disc spring 190 which is disposed on the base body 41 side of the rotary member 60 while the shaft member 75 being inserted into a shaft hole of the disc spring 190, and biases the rotary member 60 toward the flange 78. In detail, the disc spring 190 is disposed between the upper surface of the second part 74 of the mobile member 71 (i.e., the surface where the concave part 74a is formed), and a bottom surface of the rotary member 60 (i.e., a surface opposing to the upper surface of the second part 74), so that a diameter of the disc spring 190 increases as it separates from the upper surface of the second part 74 of the mobile member 71.

According to this structure, since the rotary member 60 is biased toward the flange 78 of the shaft member 75 (a shaft part) by the disc spring 190, the rotary member 60 can be prevented from being moved along the shaft member 75 when the second contacting part 62a of the rotary member 60 is in a steady state where it does not receive the reaction force R from the semiconductor wafer W.

Although in Modification 1 the biasing member is the disc spring 190, it is not limited to this. For example, a plurality of coil springs may be disposed on the base body 41 side of the rotary member 60, in a circumferential direction around the shaft member 75 having an equal interval therebetween, so that their axial directions become parallel with that of the shaft member 75. According to this structure, since the rotary member 60 is biased toward the flange 78 of the shaft member 75 (the shaft part) by the plurality of coil springs, effects similar to Modification 1 can be achieved. Note that the rotary member 60 can be biased toward the flange 78 of the shaft member 75 by other biasing members.

### Modification 2

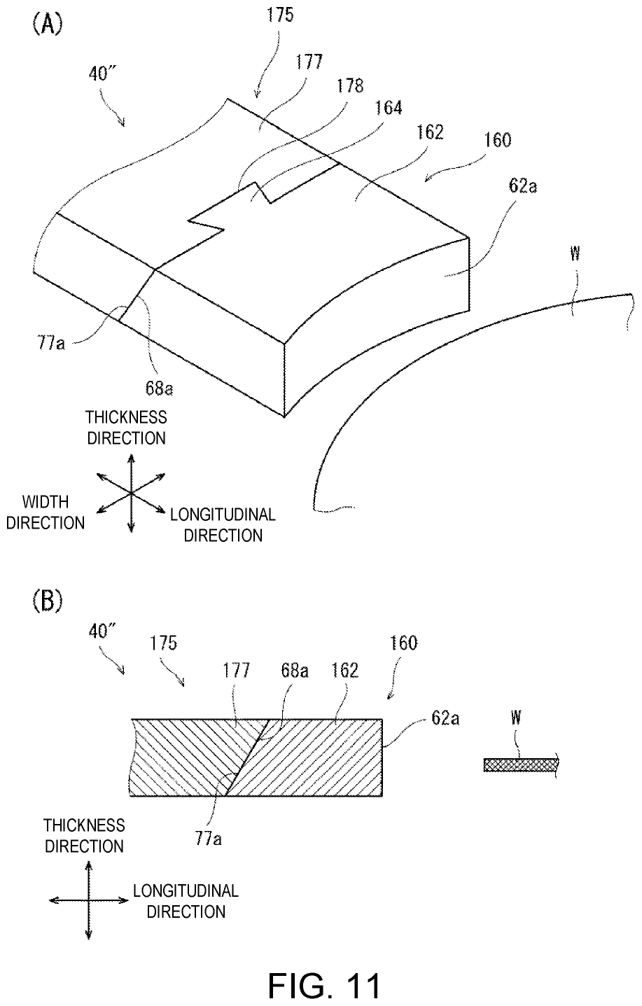

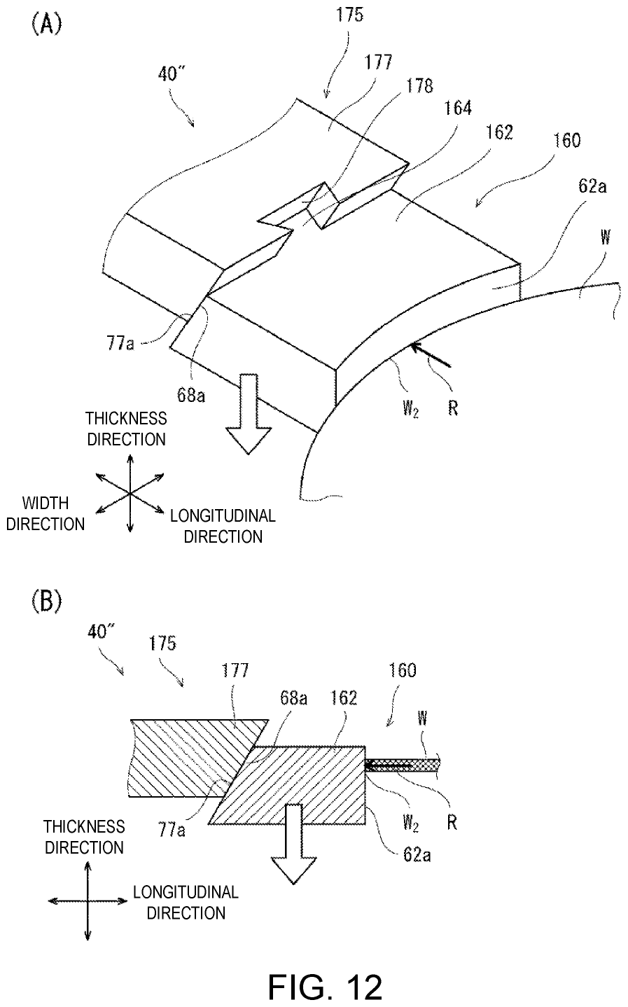

A robot hand according to Modification 2 of the embodiment described above is described with reference to FIGS. 11(A), 11(B), 12(A), and 12(B). Note that the robot hand according to this modification has the same structure as the robot hand 40 according to the embodiment, except for that the robot hand according to this modification is provided with a first member 160 instead of the rotary member 60, and a second member 175 instead of the shaft member 75. Therefore, the same reference characters are given to the same parts, and similar description is not repeated.

FIGS. 11(A) and 11(B) are enlarged views of a sliding surface, a slid surface, and their peripheral part in a state before the second contacting part receives the reaction force from the semiconductor wafer, upon the robot hand according this modification gripping the semiconductor wafer, where FIG. 11(A) is an external perspective view, and FIG. 11(B) is a cross-sectional view. FIGS. 12(A) and 12(B) are enlarged views of the sliding surface, the slid surface, and their peripheral part in a state where the second contacting part receives the reaction force from the semiconductor wafer when the robot hand according to this modification grips the semiconductor wafer, where FIG. 12(A) is an external perspective view, and FIG. 12(B) is a cross-sectional view.

As illustrated in FIGS. 11(A), 11(B), 12(A), and 12(B), a robot hand 40″ according to this modification is provided with the first member 160, and the second member 175 provided on the tip-end side of the base body 41, of the first member 160.

The first member 160 has a main part 162, and a fitting male part 166 provided protrudingly from a base-end surface (e.g., a surface on the base-end side of the base body 41) of the main part 162. The fitting male part 166 is formed to have a larger cross-sectional area as it goes toward the base end of the base body 41.

In this modification, a part of a tip-end surface of the main part 162 (i.e., a surface on the tip-end side of the base body 41) constitutes the second contacting part 62a which contacts the second part W₂ of the semiconductor wafer W. Moreover, the base-end surface of the main part 162 (i.e., the surface on the base-end side of the base body 41) and a base-end surface of the fitting male part 166 (i.e., a surface on the base-end side of the base body 41) constitute the sliding surface 68a inclining at an acute angle with respect to the base body 41 when seen in the width direction of the base body 41.

The second member 175 has a main part 177, and a fitting female part 178 bored in a tip-end surface of the main part 177 (i.e., a surface on the tip-end side of the base body 41) and fitted onto the fitting male part 164 of the first member 160. The fitting female part 178 is formed to have a larger cross-sectional area as it goes toward the base end of the base body 41 corresponding to the fitting male part 166.

In this modification, the tip-end surface of the main part 177, and an inner wall of the fitting female part 178 which contacts the base-end surface of the fitting male part 166, constitute the slid surface 77a inclining at an obtuse angle with respect to the base body 41 corresponding to the sliding surface 68a.

According to this structure, as illustrated in FIGS. 12(A) and 12(B), when the robot hand 40″ according to this modification grips the semiconductor wafer W, the sliding surface 68a of the first member 160 slides on the slid surface 77a of the second member 175 by the second contacting part 62a of the first member 160 receiving the reaction force R from the semiconductor wafer W. Accordingly, the second contacting part 62a of the first member 160 moves toward the base body 41 as indicated by white arrows in the drawing.

At this time, since the fitting male part 164 is fitted into the fitting female part 178, the first member 160 and the second member 175 are fixed to each other in the longitudinal direction of the base body 41. Also according to this mode, the second contacting part 62a can be prevented from being moved to separate from the base body 41 when receiving the reaction force R from the semiconductor wafer W.

Note that a stopper may be provided on the opposite side of the first member 160 from the sliding direction of its sliding surface 68a in the thickness direction of the base body 41 (i.e., above the first member 160 in FIGS. 11(A), 11(B), 12(A), and 12(B)), so as to regulate the movement of the first member 160 in the direction separating from the base body 41 in the thickness direction.

### Other Modifications

Although in the embodiment and the modification described above the second contacting part 62a and the sliding surface 68a are both included in the rotary member 60 (in the same member), it is not limited to this. That is, the second contacting part 62a and the sliding surface 68a may be included in separate members, as long as they can move integrally.

Although in the embodiment and the modification described above the shaft member 75 is coupled to the mobile member 71, it is not limited to this. For example, the mobile member 71 and the shaft member 75 may be integrally formed so that the entire mobile body 70 is comprised of a single member. In other words, the mobile body 70 may have a mobile part, and a shaft part which is formed integrally with the mobile part.

Although in the embodiment and the modification described above the first contacting part 52a is a part of the engaging member 50 which engages with the first part W₁ of the semiconductor wafer W, it is not limited to this. For example, the first contacting part 52a may be formed in a rectangular-parallelepiped shape, or a cube shape, and may be comprised of a member which only contacts the first part W₁ of the semiconductor wafer W without engaging therewith.

Although in the embodiment and the modification described above the second contacting part 62a is provided near the principal surface of the base part 42, it is not limited to this. That is, the second contacting part 62a may be provided in contact with the principal surface of the base part 42.

Although in the embodiment and the modification described above the base body 41 has the base part 42, and the base-branch parts 44 formed integrally with the base part 42, it is not limited to this. For example, the base body 41 may not have the base-branch parts 44 by not being branched at its tip-end side, but may be provided with one or more first contacting parts 52a at the tip-end side of the principal surface of the base body 41. Alternatively, the base body 41 may be provided with the base part 42 and three or more base-branch parts 44 formed integrally with the base part 42, and the first contacting part 52a may be provided to the principal surface of each of the three or more base-branch parts 44.

Although in the embodiment and the modifications described above the substrate is the semiconductor wafer W in the disc-shape, it is not limited to this. For example, the substrate may be a semiconductor wafer in a rectangular plate-shape when seen in its thickness direction, a semiconductor wafer in another shape, or a substrate other than a semiconductor wafer.

Although in the embodiment and the modifications described above the robot 20 is the horizontally articulated 3-axis robot having the turnable wrist part 36, it is not limited to this. For example, the robot 20 may not have the turnable wrist part 36, or may be configured as a horizontally articulated robot with one, two, or four or more axes. Alternatively, the robot 20 may be configured as a polar coordinate robot, a cylindrical coordinate robot, a Cartesian coordinate robot, a vertically articulated robot, or another robot.

Although in the embodiment and the modifications described above the accommodating device 110 has a structure in which the semiconductor wafer W is vertically accommodated so as to extend in the vertical direction, it is not limited to this. For example, the accommodating device 110 may have a structure in which the semiconductor wafer W is horizontally accommodated so as to extend in the horizontal direction.

Although in the embodiment and the modifications described above the robot system 10 is provided with the accommodating device 110 which accommodates the semiconductor wafer W (the substrate), it is not limited to this. For example, the robot system 10 may not have the accommodating device 110, but may have a plurality of processing devices which apply processing to the semiconductor wafer W. Then, the robot system 10 may transfer the semiconductor wafer W by the robot 20 between the plurality of processing devices while gripping it. Note that the processing applied to the semiconductor wafer W by the plurality of processing devices may be, for example, heat treatment, impurity introduction, thin-film formation, lithography processing, cleaning, etching, or other processings.

### DESCRIPTION OF REFERENCE CHARACTERS

10 Robot System
20 Robot
22 Pedestal
24 Lifting Shaft
30 Robotic Arm
32 First Link
34 Second Link
36 Wrist Part
38 Hand-base Part
40 Robot Hand
41 Base Body
42 Base Part
43 Notch
44 Base-branch Part
50 Engaging Member
51 Inclining Surface
52 Standing Surface
52a First Contacting Part
53 Flange
55 Guiding Member
56 Inclining Surface
57 Standing Surface
60 Rotary Member
62 Circular Edge
62a Second Contacting Part
68 Shaft Hole
68a Sliding Surface
70 Mobile Body
71 Mobile Member
72 First Part
74 Second Part
74a Concave Part
75 Shaft Member
76 Base-end Part
77 Tapered Part
77a Slid Surface
78 Flange
80 Rail Member
90 Robot Controlling Device
110 Accommodating Device
112 Shell
114 Bottom Plate
116 Bottom-plate Groove
124 Back Plate
126 Back-plate Groove
160 First Member
162 Main Part
164 Fitting Male Part
175 Second Member
177 Main Part
178 Fitting Female Part
190 Disc Spring
200 Conventional Robot Hand
201 Base Body
202 Rotary Member
202a Second Contacting Part
204 Mobile Body
206 Mobile Member
208 Shaft Member
AX₁ First Axial Line
AX₂ Second Axial Line
AX₃ Third Axial Line
AX′ Turning Axial Line
R Reaction Force
T Thrust
W Semiconductor Wafer
W₁ First Part
W₂ Second Part

1. A robot hand configured to grip a substrate by contacting an edge of the substrate at at least two locations, comprising:
a base body defining a longitudinal direction connecting a base end to a tip end thereof, a width direction orthogonal to the longitudinal direction, a thickness direction orthogonal to the longitudinal direction and the width direction, a center line extending in the longitudinal direction at the center in the width direction, and a gripping position at which the center of the substrate is located on the center line extending in the longitudinal direction;
a first contacting part provided to the base body at the tip-end side and configured to contact a first part of the edge of the substrate when the substrate is gripped;
a second contacting part provided on the base-end side of the base body and configured to contact a second part of the edge of the substrate on the center line extending in the longitudinal direction when the substrate is gripped;
a sliding surface provided on the base-end side of the second contacting part on the center line extending in the longitudinal direction, and configured to move integrally with the second contacting part; and
a mobile body having a slid surface provided on the base-end side of the sliding surface on the center line extending in the longitudinal direction, and configured to, upon the substrate being gripped, move toward the tip end on the center line extending in the longitudinal direction to push the sliding surface by the slid surface and move the sliding surface and the second contacting part toward the tip end,
wherein the sliding surface inclines at an acute angle with respect to the base body when seen in the width direction,
wherein the slid surface inclines at an obtuse angle with respect to the base body corresponding to the sliding surface when seen in the width direction, and
wherein when the substrate is gripped, the second contacting part receives a reaction force from the substrate and the sliding surface slides on the slid surface to move the second contacting part toward the base body.

2. The robot hand of claim 1, wherein both of the second contacting part and the sliding surface are included in the same member.

3. The robot hand of claim 2, further comprising a rotary member having a circular edge, and a shaft hole bored at the center thereof when seen in the thickness direction,
wherein the second contacting part is a part of the circular edge of the rotary member,
wherein the sliding surface is a part of an inner wall of the shaft hole of the rotary member,
wherein the mobile body has a shaft part to be inserted into the shaft hole of the rotary member to rotatably support the rotary member in a plane where the longitudinal direction intersects with the width direction,
wherein the shaft part has a tapered part having a cross-sectional area that decreases toward the base body, and
wherein the slid surface is a part of an outer surface of the tapered part of the shaft part.

4. The robot hand of claim 3, wherein the shaft part further has a flange on a side separating from the base body more than the tapered part,
the robot hand further comprising a biasing member provided on the base-body side of the rotary member while the shaft part is inserted into a shaft hole of the biasing member, and configured to bias the rotary member toward the flange.

5. The robot hand of claim 1, further comprising a motion regulating structure configured to regulate a movable range of the second contacting part and the sliding surface with respect to the slid surface.

6. The robot hand of claim 1, wherein, in the thickness direction, an application point of the reaction force from the substrate to the second contacting part differs from an application point of a thrust that moves the mobile body toward the tip end on the center line extending in the longitudinal direction.

7. The robot hand of claim 1, wherein the base body has a base part provided on the base-end side thereof, and at least two base-branch parts branching from the base part and extending toward the tip end, and
wherein the second contacting part is provided near or in contact with a principal surface of the base part, and the first contacting part is provided protrudingly from a principal surface of each of the at least two base-branch parts.

8. The robot hand of claim 1, wherein the substrate is a semiconductor wafer in a disc-shape, and
wherein the first contacting part has an arc-shape corresponding to the edge of the semiconductor wafer when seen in the thickness direction.

9. The robot hand of claim 1, wherein the first contacting part is a part of an engaging member configured to engage with the first part of the edge of the substrate when the substrate is gripped.

10. A robot, comprising:
the robot hand of claim 1; and
a robotic arm to which the robot hand is attached at a tip end of the robotic arm,
wherein the robot changes at least a posture of the robotic arm to transfer the substrate while the robot hand grips the substrate.
